(19) United States
(12) Patent Application Publication
(10) Pub. No.: US 2025/0093441 A1
(43) Pub. Date: Mar. 20, 2025

(54) SWITCH-ISOLATED SINGLE-CIRCUIT Q-SPOILING AND PREAMP DECOUPLING

(71) Applicant: Inkspace Imaging, Inc., Pleasanton, CA (US)

(72) Inventors: Tracy Allyn Wynn, Pleasanton, CA (US); Gillian Gentry Haemer, Pleasanton, CA (US); Joseph Russell Corea, Fremont, CA (US); Pulkit Malik, Dublin, CA (US)

(21) Appl. No.: 18/888,581

(22) Filed: Sep. 18, 2024

Related U.S. Application Data
(60) Provisional application No. 63/539,322, filed on Sep. 19, 2023.

(51) Int. Cl. G01R 33/36

(52) U.S. Cl. CPC G01R 33/3614; G01R 33/3621; G01R 33/3628

(57) ABSTRACT

A radio frequency (RF) receive circuit for use in a magnetic resonance imaging (MRI) scanner, comprising: an antenna including multiple reactive impedance elements coupled in a loop configuration; an amplifier input impedance; a first transmission line coupled in parallel with at least one reactive impedance element; a second transmission line coupled in parallel with the amplifier input impedance; a first reactive impedance circuit between the first transmission line and the second transmission line; an RF switch configured to isolate a second combined impedance, that includes the second transmission line and the amplifier input impedance, from a first combined impedance, that includes the first transmission line and the first reactive impedance circuit, when the RF switch is closed and to couple the second combined impedance to the first combined impedance when the RF switch is open; wherein, when the RF switch is closed, the first combined impedance transforms impedance of the RF switch to be in resonance with the at least one antenna impedance element; and wherein, when the RF switch is open, the first combined impedance and the second combined impedance together transform of the amplifier input impedance to be in resonance with the at least one antenna impedance element.

### CROSS-REFERENCE TO RELATED APPLICATION

This patent application claims the benefit of U.S. Provisional Patent Application No. 63/539,322 filed Sep. 19, 2023, entitled, “Diode-Isolated Single Circuit Q-Spoling and Preamp Decoupling”, which is expressly incorporated by reference herein in its entirety.

### STATEMENT REGARDING FEDERALLY SPONSORED RESEARCH OR DEVELOPMENT

This invention was made with government support under 5R44EB028728-03 awarded by the National Institutes of Health (NIH). The government has certain rights in the invention.

### BACKGROUND

Magnetic Resonance Imaging (MRI) is used to image biological tissue by creating an environment where a nuclear magnetic resonance (NMR) signal is generated. To do this, a sample, e.g., a patient or animal, is first placed in a uniform magnetic field (B₀), which is oriented along the Z axis in x/y/z Cartesian space, to create a net magnetic moment parallel to the field of the sample's nuclear magnetic spins. While in the B₀ field, a high-power radio frequency (RF) excitation pulse of energy is applied to create Larmor precession of protons in the x-y plane. This is known as the transmit mode of an MRI scan, with the applied RF excitation pulse, commonly referred to as the transmit pulse, as the transmit field, or as the B₁⁺ field. This transmit pulse is applied at a frequency known as the Larmor frequency, determined by the field strength (B₀) of the scanner and the gyromagnetic ratio of the sample's atomic nuclei of interest following the equation below, where y is a known constant for a given element:

ƒₗₐᵣₘₒᵣ=B₀*(γ/2π)

Due to the abundance of water in the human body and the nuclear properties of hydrogen, the majority of clinical MR images are acquired using the signals from hydrogen nuclei (γ=42.6 MHz/Tesla). Therefore, for clinical MRI at 1.5T and 3T, ƒₗₐᵣₘₒᵣ is approximately 64 MHz and 128 MHz, respectively.

Once the transmit field is turned off, the excited nuclei will gradually relax back to their resting state, oriented parallel to the Bo field. This period of gradual relaxation is known as the RF receive mode of an MRI scan. The transmit field excitation pulse(s) cause the spins of the nuclei to be “tipped” creating localized changing magnetic moments at the nuclei. The relaxation causes this created magnetic signal to decay. Differences in decay time between different materials is how MRI achieves contrast between different tissues in the body. The localized changing magnetic moments, can be converted into an electrical signal, referred to as a receive signal, using Faraday's law of induction, by placing a loop of wire near the sample. Loops of wire known as receive antennas, channels, elements, or antennas can be placed at different locations at a sample, e.g., overlaying different portions of a patient's body, to capture magnetic energy emanating from such different locations. In practice other RF antennas that are sensitive to the magnetic and electric fields at the Larmor frequency also can be used as receive antennas (e.g. dipole, stripline, birdcage, patch antenna, etc.).

Images are acquired in MRI by manipulating the field during the transmit mode of the scan with gradient antennas, which manipulate Bo in the x, y, or z direction in order to encode the spins with spatial information. During the RF receive mode, the resulting signals produced by the nuclei of interest are transformed into electrical RF receive signals in the local receive antennas, which then can be passed to MRI scanner processing circuitry, decoded, and reconstructed into cross-sectional or volumetric images of the sample.

Because the receive signal acquired by the receive antenna is converted directly into images, the quality of the receive signal directly impacts the clinical image quality. To help increase the amount and quality of the receive signal, receive antennas, generally are placed as close to the surface of a sample volume of interest as possible, to increase the amount of Faraday induction that occurs. Receive antennas typically are tuned to be resonant at the Larmor frequency, ƒₗₐᵣₘₒᵣ, by adjusting the amount of inductance and/or capacitance in the receive loop to further increase their sensitivity to the frequency of interest.

However, in order to place a receive antenna as close as possible to the region of interest, a receive antenna ordinarily must be placed directly within the high power transmit field, B₁⁺. Because the transmit pulse is applied at the Larmor frequency, it is capable of driving a significant current on a receive antenna that is resonant at the Larmor frequency. This current could be capable of distorting the transmit field, destroying the resulting image and presenting a significant safety risk to the patient and to the MRI system. Therefore, to function correctly a surface antenna must be sensitive to the lower power magnetic energy present during relaxation of excited nuclei back to their resting state during the receive portion of the scan and invisible to the high-power magnetic energy present during the transmit portion of the scan.

To operate safely and efficiently and to avoid damage, during the RF transmit portion of the MRI sequence, each MRI receive antenna (element) ordinarily is magnetically decoupled from an MRI system's primary RF transmit antenna during the RF transmit portion of the MRI sequence. This is commonly known as “decoupling” or “Q-spoiling.” It is typically performed by creating a switchable parallel-resonant LC circuit in series with the antenna loop itself. When switched on so that the parallel-resonant LC circuit is active, a large impedance is created in the loop antenna, sharply reducing the amount of current that can flow and proportionally limiting the magnetic field that can be generated or received. An alternative description of this function is that by activating this parallel-resonant LC circuit, which includes at least one of the reactive (i.e., L or C) components in the resonant loop antenna, two high-Q resonant circuits are tightly coupled, resulting in “peak-splitting” and sharply reducing the overall circuit's sensitivity at the frequency of interest. U.S. Pat. No. 6,747,452, entitled, “Decoupling Circuit for Magnetic Resonance Imaging Local Coils”, discloses a local receive antenna operatively coupled both to an active decoupling circuit and to a passive decoupling circuit. The active detuning circuit generally acts as the primary mechanism to detune the receive antenna during the transmit mode and the passive detuning circuit generally acts as a backup that automatically detunes the antenna if the active detuning circuit fails to do so during the transmit mode.

MRI receive arrays are often multichannel (i.e., having more than one antenna in close proximity to the patient) to take advantage of image acceleration techniques allowing for faster exam times. MRI receive elements are also decoupled from each other during the receive portion of the MRI sequence so as to minimize RF energy shared between them. More particularly, it is necessary to ensure that current induced on one antenna loop is not parasitically shared in other nearby antenna loops of coils. This decoupling allows each element to function more independently and free of the influence of its neighbors. This independence can markedly reduce correlated noise between elements, increasing signal-to-noise ratio (SNR) in many cases. The technique most often employed to do this is commonly known as “preamp decoupling,” so named because it uses the input impedance of the receive element's amplifier, which, typically comprises a low noise amplifier (LNA), as part of another parallel-resonant circuit, reducing the amount of current that can flow in each antenna loop, and proportionally reducing the amount of magnetic field that can be generated in each antenna that may be coupled with its neighbors. In other words, during receive mode, the input impedance of a receive circuit's amplifier is coupled with another parallel resonant circuit to produce a high impedance at a receive antenna, which limits current flow within that antenna, which in turn, reduces RF electromagnetic energy transmitted by that antenna, which thereby limits inducing by that antenna of parasitic current in a nearby antenna. This technique was disclosed by Roemer, P. B., et. al., “The NMR Phased Array,” Magnetic Resonance in Medicine, pp. 192-225, November 1990.

Separate circuits generally have been used for the Q-spoil function and the preamp decoupling function. Savings in size and cost sometimes can be realized by co-locating, or even combining these circuits, but typically at the cost of complexity, as it often becomes difficult to electrically isolate the circuits from each other. Physical separation of the Q-spoiling and preamp decoupling circuits can consume valuable space and can increase component count, and therefore cost. However, co-locating these circuits can result in coupling between them, degrading their function, and/or increasing the difficulty of tuning and testing them. Thus, there has been a need for a more compact circuit for performing Q-spoil during transmit mode and for performing preamp decoupling during receive mode, while avoiding degradation of performance from coupling of Q-spoil circuit elements with preamp decoupling circuit elements.

### SUMMARY

A radio frequency (RF) receive circuit is provided for use in a magnetic resonance imaging (MRI) scanner. The RF circuit includes an antenna including multiple reactive impedance elements electrically coupled in a loop configuration and an amplifier input impedance. A first transmission line is electrically coupled to at least one reactive impedance element from the antenna. A second transmission line is electrically coupled to the amplifier input impedance. A first reactive impedance circuit is electrically coupled to the first transmission line and with the second transmission line, between the first transmission line and the second transmission line. An RF switch circuit is electrically coupled between a first combined impedance and a second combined impedance. The first combined impedance includes the first transmission line and the first reactive impedance circuit. The second combined impedance includes the second transmission line and the amplifier input impedance. The RF switch circuit is operable to electrically isolate the second combined impedance from the first combined impedance when the RF switch is closed and to electrically couple the second combined impedance to the first combined impedance when the RF switch is open. The first combined impedance is configured such that, when the RF switch is closed, the first combined impedance transforms impedance of the RF switch circuit to be in resonance with the at least one antenna impedance element. The first and second combined impedances are collectively configured such that, when the RF switch is open, the first combined impedance and the second combined impedance together transform the amplifier input impedance to be in resonance with the at least one antenna impedance element.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. In addition, the present disclosure may repeat reference numerals and/or letters in the various examples. This repetition is for simplicity and clarity and does not in itself dictate a relationship between the various embodiments and/or configurations discussed.

FIG. 1 is an illustrative drawing showing RF transmit antenna and RF receive antennas arranged in relation to a patient within an MRI scanner system.

FIG. 2 is an illustrative circuit diagram showing an example receive circuit, which includes an amplifier circuit operatively coupled to an MRI signal processing system.

FIG. 3 is an illustrative schematic diagram representing an infinitesimal segment of an example transmission line.

FIGS. 4A-4B are illustrative schematic diagrams that show respective first and second example “Pi” LC circuit configurations of the impedance matching circuit.

FIG. 5A-5B are illustrative schematic diagrams that show respective first and second example “Tee” LC circuit configurations of the impedance matching circuit.

FIG. 6A-6B are illustrative schematic diagrams that show respective first and second example “L” LC circuit configurations of the impedance matching circuit.

FIG. 7 is an illustrative drawing representing a diode implementation of a switch circuit.

FIG. 8 is an illustrative drawing representing a cross-coupled diode implementation of a switch circuit.

### DETAILED DESCRIPTION

### Receive Circuit

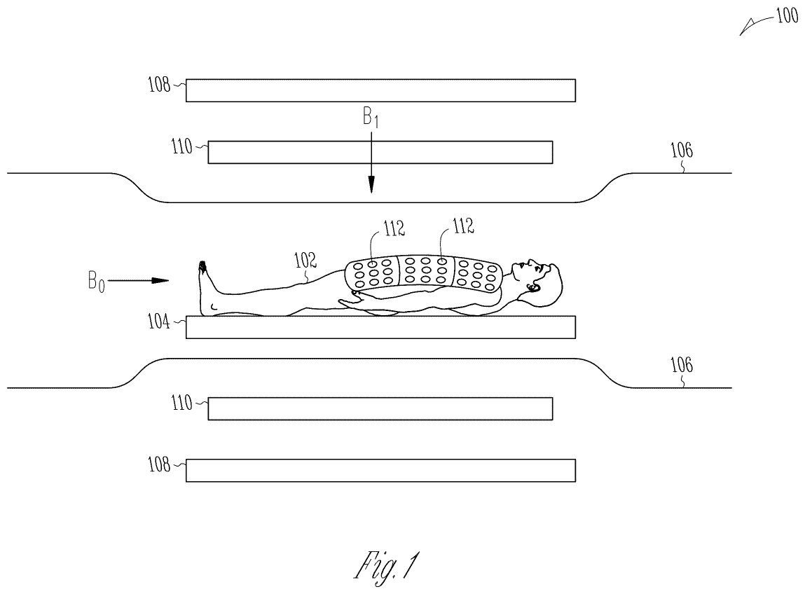

FIG. 1 is an illustrative drawing showing RF transmit antenna 110 and RF receive antennas 112 arranged in relation to a patient within an MRI scanner system 100. It is noted that in the MRI context, an antenna often is referred to as a “loop” or as a “coil”. A subject patient 102 is shown laying on a platform 104 within an MRI chamber 106. A main magnet 108 is arranged to produce a static B₀ magnetic field. During excitation mode, one or more transmit antennas 110 transmit an excitation magnetic field pulse that produces a B₁ magnetic field perpendicular to the static Bo magnetic field at the frequency of interest. Multiple receive antennas 112 are located in close proximity to the patient's body. During RF receive mode, changes in magnetic flux produced by precession of net nuclear magnetization within the subject, following RF-excitation, induces an MR current within the receive antennas 112 that can be post-processed by an MRI signal processing system to extract frequency, phase, and amplitude information used to construct an MR image.

FIG. 2 is an illustrative circuit diagram showing an example receive circuit 202, which includes a receive antenna 204 and an amplifier circuit 206 operatively coupled to an MRI signal processing system 208. More particularly, the receive circuit 202 includes the receive antenna 204, a first transmission line 210, a first reactive impedance circuit 212, an RF switch circuit 214, a matching impedance circuit 216, a second transmission line 218, a second reactive impedance circuit 220, and the amplifier circuit 206 which includes an input impedance 223.

The antenna 204 comprises a loop or coil of conductive material that can be positioned within the EM fields produced during MRI scans. The antenna is configured to be sensitive to variations in the EM fields at the Larmor frequency. During RF receive mode, magnetic flux from the precession of excited nuclei back to their resting state induces an RF receive signal in the antenna 204 at a receive signal frequency, such as at the Larmor frequency.

An example antenna 204 includes discrete reactive antenna impedance elements 222 electrically connected in a loop configuration by conductors 221. In the example antenna 204, the reactive antenna impedance elements 222 include respective discrete capacitors 224 and the conductors 221 may exhibit inherent inductive impedance. Alternative reactive antenna impedances (not shown) can include multi-capacitor circuits, inductor circuits, or circuits containing a combination of capacitors and inductors. Different ones of the reactive antenna impedance elements 222 may have different values, and one or more of the antenna reactive impedance elements 222 and/or inductances of conductor segments 221 may be adjustable to tune a resonant frequency of the antenna 204 to a prescribed receive signal frequency such as to a Larmor frequency used by the example MRI scanner 100.

The amplifier circuit 206 is configured to amplify the signals received at its input. An example amplifier 206 has an input impedance 223 having a predetermined impedance value that typically is relatively small (e.g., near 1Ω) and mostly resistive.

The first transmission line 210 includes an inner conductor signal conductor 226A surrounded by an outer conductor 228A. The second transmission 218 includes an inner conductor signal conductor 226B surrounded by an outer conductor 228B. An antenna impedance element 222′ is electrically coupled in parallel with the first transmission line 210 at a first end portion 210-1 of the first transmission line 210. More particularly, the antenna impedance element 222′ is electrically coupled between the inner conductor signal conductor 226A and the outer conductor 228A at the first end portion 210-1 of the first transmission line 210. The RF switch 214 is operatively coupled between the first and second transmission lines 210, 218.

The RF switch 214 is operable to open to electrically couple the first transmission line and second transmission lines 210, 218 in series with one another and is operable to close electrically isolate the first and second transmission lines 210, 218 from one another. The RF switch 214 is configured to transition to a close state based upon a signal transmitted within the receive circuit 202 having a voltage magnitude and to otherwise behave in an open state. More particularly, the RF switch 214 is coupled in parallel with the first and second transmission lines 210, 218 at a location between the first and second transmission lines 210, 218. The first transmission line 210 is located on a first side 230A of the RF switch 214, and the second transmission line 218 is located on a second side 230B of the RF switch 214. When the RF switch 214 is open components of the receive circuit 202 located on first and second sides 230A, 230B of the RF switch 214 are in electrical communication with one another. When the RF switch 214 is closed, components of the receive circuit 202 located on the second side 230B of the RF switch 214 are isolated from components of the receive circuit 202 located on the first side 230A of the RF switch 214. Thus, when the RF switch 214 is closed, components of the receive circuit 202 located on the second side 230B of the RF switch 214 are electrically isolated from the antenna impedance element 222′, and when the RF switch 214 is open, components of the receive circuit 202 located on the second side 230B of the RF switch 214 are electrically coupled to the antenna impedance element 222′.

The impedance matching circuit 216 has an impedance selected to match impedances on opposite sides 230A, 230B of the RF switch circuit 216. The RF switch 214 is operatively located to have the first transmission line 210 and the first reactive impedance circuit 212 on the first side 230A of the RF switch 214 and to have the second transmission line 218, the second reactive impedance circuit 220, and the amplifier input impedance 223 on the second side 230B of the RF switch circuit 214. The impedance matching circuit 216 has an impedance selected to match a first combined impedance that includes impedance of the first transmission line 210 and the first reactive impedance circuit 212 on the first side 230A of the switch circuit 214 with a second combined impedance that includes impedance of the second transmission line 218, the second reactive impedance circuit 220, and the amplifier input impedance 223 on the second side 230B of the RF switch circuit 214, so as to prevent reflection of receive signals during receive mode operation.

The first reactive impedance circuit 212 is operatively coupled in parallel with the antenna impedance matching element 222′ on the first side of the RF switch 214 between a second end portion 210-2 of the first transmission line 210 and the RF switch 214. When the RF switch 214 is closed, the first transmission line portion 210 and the first reactive impedance 212 have the first combined impedance selected to perform a Q-spoiling function at a prescribed frequency, which can be the Larmor frequency, such that the first transmission line 210 and the first reactive impedance 212 transform an impedance of the closed RF switch element 214 to be in resonance with the antenna impedance matching element 222′ such that impedance across the antenna impedance element 222′ is increased, thereby reducing current within the antenna 204 to prevent harm to the patient and to prevent loss of image quality due to distortion of the system's transmit field. Thus, during excitation mode operation of an MRI system based upon a signal excited within the antenna 204 at the prescribed frequency (e.g., Larmor frequency) reaches a turn-on value of the RF switch 214, the switch 214 closes and the Q-spoiling function, performed using the first transmission line 210 and the first reactive impedance 212, blocks the excitation mode frequency signal from transmission within the receive circuit 202.

The amplifier input impedance 223 is electrically coupled in parallel with the second transmission line 218. The second reactive impedance circuit 220 is electrically coupled in parallel with the second transmission line 218 between a second end portion 210-2 of the second transmission line 218 and the input impedance 223 of the amplifier circuit 206. As stated above, when the RF switch 214 is open, the first transmission line 210 and the second transmission line 218 are electrically coupled in series. Moreover, when the RF switch 214 is open, the amplifier input impedance 223 is electrically coupled with the antenna impedance matching element 222′. More particularly, when the RF switch 214 is open, the first combined impedance (comprising the first transmission line 210, the first reactive impedance 212, and the matching impedance 216) and the second combined impedance (comprising the second transmission line 218, the second reactive impedance 220, and the amplifier input impedance 223), operating together, are in resonance with the antenna impedance element 222′at a prescribed frequency, which can be the Larmor frequency. As a result, when the RF switch 214 is open, the input impedance 223 of the amplifier circuit 206 is transformed into an impedance that is in resonance with the antenna impedance matching element 222′, thereby creating a parallel resonant circuit having a high impedance across the antenna impedance matching element 222′, effectively blocking current in the antenna 204. Thus, during receive mode operation of an MRI system, when a signal is excited within the antenna 204 at the prescribed frequency (e.g., Larmor frequency) that does not reach a turn-on value of the RF switch 214, the switch 214 is open and the first combined impedance (210, 212, 216) and the second combined impedance (218, 220, 223) operate together to transform an impedance of the amplifier input circuit 223 seen at the first end portion 210-1 to be in resonance with the antenna impedance element 222′. In an example embodiment, the transformed impedance of the amplifier input circuit 223 has a value that is greater than an impedance of the antenna impedance element 222′, thereby reducing current within the antenna 204, while permitting transmission of a voltage signal from the antenna 204 to the amplifier circuit 206. The reduced current within the antenna 204 reduces parasitic induction with neighbor antennas (not shown).

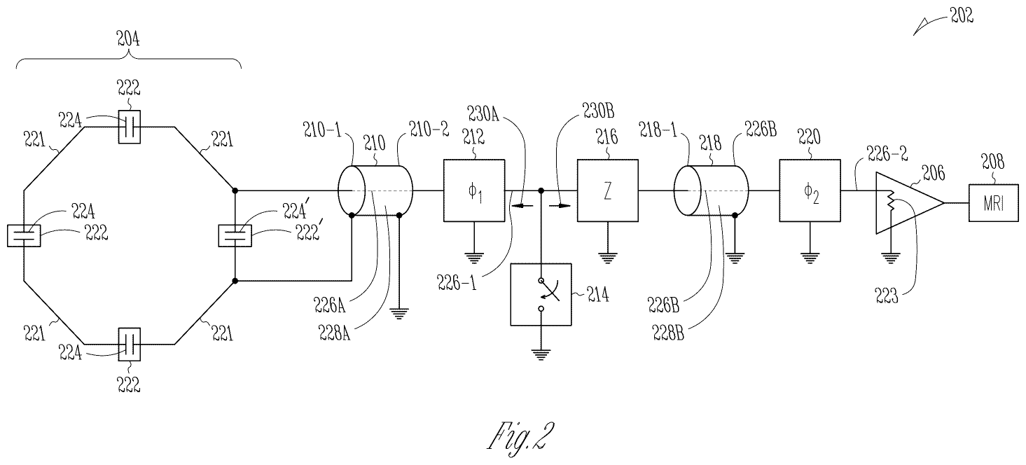

FIG. 3 is an illustrative schematic diagram representing a infinitesimal segment 300 of an example transmission line. Any transmission line has a “characteristic impedance,” which is determined by the Rdx, Ldx, Gdx, and Cdx of FIG. 3. For a given construction, this is, in general, frequency-dependent (though as Rdx tends to zero and Gdx to infinity, frequency dependence begins to disappear). The characteristic impedance is the value of impedance required of a source or a termination to prevent signal reflection. If we consider a particular termination (or source) impedance having a specific value, and then attach a transmission line to that impedance, as we move along the transmission line away from the impedance, the impedance we measure at any point along the length of that line changes, rotating clockwise around the Smith chart). If we start at the edge of the Smith chart (where a zero-ohm short would be) rotating around the edge of the chart yields pure inductances and capacitances. This invention exploits that phenomenon. Persons skilled in the art will understand that impedance of a transmission line varies with frequency dependent phase length of the transmission line. The phase length of transmission line, in turn, translates to an impedance presented by a transmission line. For example, if there is a prescribed impedance that is a low impedance connected at one end of a transmission line then that impedance as seen from the other end of the transmission line will vary with the length of the transmission line. Eventually, the low impedance will look like a high impedance as seen from the other end of the transmission line. Add enough additional length, and the prescribed impedance will once again look like a low impedance from the other end of the transmission line. In between ends of the transmission line, the prescribed impedance will assume a range of capacitive or inductive values. Moreover, the phase length of a transmission line may transition more than once through a zero phase length value with increasing transmission line length. A Smith Chart is a well-known analytical tool that allows easy calculation of the transformation of a complex load impedance through an arbitrary length of transmission line.

An example first transmission line 210 comprises a coaxial cable that includes an inner conductor signal conductor 226A surrounded by an outer conductor 228A. The example first transmission line 210 has a first end portion 210-1 and a second end portion 210-2. The outer conductor 228A is connected to ground, also referred to as a ground conductor. In an example embodiment, a respective one of the antenna reactive impedance elements 222 is electrically connected in parallel with the first end portion 210-1 of the first transmission line 210 between the inner conductor signal line 226A and the outer conductor 228B, also referred to as a ground conductor. In an example embodiment, an example reactive impedance matching element 222′, also referred to as an antenna matching impedance, is connected in parallel with the first transmission line 210 and is used to set a characteristic impedance of the overall antenna loop structure. In the following description, the antenna matching impedance 222′ is a capacitance 224′. However, it will be appreciated that alternative antenna matching impedances can include multi-capacitor circuits, inductor circuits, or circuits containing a combination of capacitors and inductors. An alternative example first transmission line (not shown) may comprise a twisted pair, microstrip, or strip line, for example. The first reactive impedance circuit 212 is electrically coupled to the second end portion 210-2 of the first transmission line 210 between the signal conductor signal conductor 226A and electrical ground potential.

The first reactive impedance circuit 212 is selected to have an impedance to impart a phase length, which may be positive or negative, such that the impedance of switch 214, referenced through the collective phase lengths of the first transmission line 210 and the first reactive capacitance 212 present an impedance at the first end portion 210-1 of the first transmission line in resonance with the antenna reactive impedance matching element 222′. It is noted that if the first transmission line 210 on its own transforms impedance at the first end portion 210-1 to an impedance that is resonant with the antenna impedance matching element 222′, then there would be no need for the first reactive impedance 212, which could be omitted from the receive circuit 202.

An example second transmission line 218 comprises a coaxial cable that includes an inner conductor signal conductor 226B surrounded by an outer conductor 228B. The example second transmission line 218 has a first end portion 218-1 and a second end portion 218-2. The outer conductor 228B is connected to ground. In an example embodiment, the second reactive impedance circuit 220 is electrically coupled to the second end portion 218-2 of the second transmission line 218 between the signal conductor signal conductor 226B and electrical ground potential. The second reactive impedance circuit 220 also is electrically connected in parallel with the input impedance 223 of the amplifier circuit 206. More particularly, the second reactive impedance 220 and the input impedance 223 are electrically connected in parallel between a signal conductor 226-2 and ground potential.

The impedance matching circuit 216 is electrically coupled between the first reactive impedance circuit 212 and the second transmission line 218. More particularly, the first reactive impedance circuit 212 and the circuit 216 are electrically connected in parallel between a signal conductor 226-1 and ground potential. The impedance matching circuit 216 may also impart some positive or negative phase to the signal passing through it.

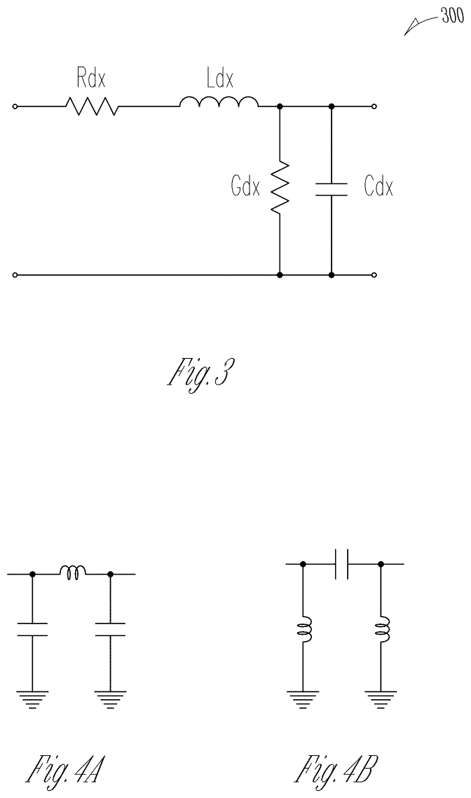

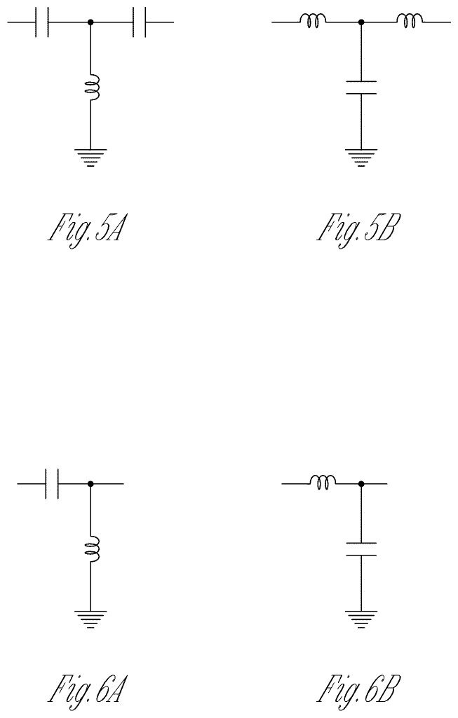

FIGS. 4A-4B are illustrative schematic diagrams that show a first example “Pi” LC circuit configuration 402 of the impedance matching circuit 216 and a second example “Pi” LC circuit configuration 404 of the matching circuit 216, respectively. FIG. 5A-5B are illustrative schematic diagrams that show a first example “Tee” LC circuit configuration 502 of the impedance matching circuit 216 and a second example “Tee” LC circuit configuration 504 of the matching circuit 216, respectively. FIG. 6A-6B are illustrative schematic diagrams that show a first example “L” LC circuit configuration 602 of the impedance matching circuit 216 and a second example “L” LC circuit configuration 604 of the matching circuit 216, respectively.

The respective first and second reactive impedance circuits 212, 220 also can be implemented using any of the example “Pi”, “Tee”, or “L” circuit topologies of FIGS. 4A-6B.

The length of the second transmission line 218, together with a characteristic impedance value of the second transmission line 218, and a frequency of operation of the receive circuit 202 determines a frequency-dependent electrical phase length of the second transmission line 218. As explained above, frequency-dependent phase length of a transmission line may translate the impedance presented at one end to a different impedance value at the other end.

The second reactive impedance circuit 220 is selected to have an impedance to impart a phase length, which may be positive or negative, such that collective phase lengths of the second transmission line 218, the second reactive capacitance 220, the matching impedance 216, the first reactive impedance 212 and the first transmission line 210 transform an impedance seen at the 223 to have an impedance value in resonance with the antenna impedance matching element 222′. It is noted that if the second transmission line 218 in combination with impedances of components 216, 212 and 210 transforms an impedance at 223 to an impedance at the first end portion 210-1 that is resonant with the antenna impedance matching element 222′, then there would be no need for the second reactive impedance 220, which could be omitted from the receive circuit 202.

As explained above, the impedance matching circuit 216 is operative to match impedance of the first transmission line 210 and the first reactive impedance circuit 212 on first side 230A of the switch circuit 214 with impedance of the second transmission line 218 and the second reactive impedance matching circuit 220 on the second side 230B of the switch circuit 214 so as to prevent reflection of receive signals during receive mode operation. If the impedances on the opposite sides of the switch circuit are matched, then there is no need for the impedance matching circuit 216.

It will be appreciated that the circuit 202 includes a signal conductor path that extends through components 210, 212, 216, 218, and 220, and that includes conductors 226A, 226-1, 226B, and 226-2.

The switch circuit 214 is electrically connected in parallel between the first reactive impedance circuit 212 and the matching impedance circuit 216. More particularly, the switch circuit 214 is electrically connected between signal conductor path at signal conductor 226-1 and electrical ground. Moreover, the switch circuit 214 is operatively positioned between the first transmission line 210 and the first reactive impedance 212 on the first side 230A thereof and the second transmission line 218 and the second reactive impedance on the second side 230B thereof, such that when the switch circuit 214 is closed, the first reactive impedance 212 on the first side 230A and the second transmission line 218 and the second reactive impedance on the second side 230B, are electrically isolated from one another. It is noted that his function is dependent upon the impedance of 214 being very low, so as to dominate the total impedance seen when standing at 226-1 and looking to the right (in FIG. 2). This is noted in the next section.

### MRI Transmit Mode Operation of the Receive Circuit

During MRI transmit mode operation, the switch circuit 214 is closed, it provides a low resistance path, having no reactive impedance, between signal conductor 226-1 and ground. The receive circuit 202 uses the first transmission line portion 210 and the first reactive impedance 212 to perform a Q-spoiling function in which the first transmission line 210 and the first reactive impedance 212 transform the impedance of switch element 214 to be in resonance with the antenna impedance matching element 222′ that is coupled to the first end portion 210-1 of the first transmission line 210. As a result, impedance across the antenna impedance matching element 222′ is increased, thereby reducing current within the antenna 204 to prevent harm to the patient and to prevent loss of image quality due to distortion of the system's transmit field.

The switch circuit 214 is electrically connected in parallel with the matching impedance 216, the second transmission line 218, the second reactive impedance 220, and the amplifier input impedance 223. When closed, the switch circuit 214 provides a nonreactive impedance having a resistance value that is sufficiently small as to dominate over the collective impedances of the matching impedance 216, the second transmission line 218, the second reactive impedance 220, and the amplifier input impedance 223, as seen within the receive circuit 202 at a location of the closed switch circuit 214. In other words, in effect, an RF short circuit results between signal conductor 226-1 and ground in response to closing the switch circuit 214, which electrically isolates the first transmission line 210 and the first reactive impedance 212 that are used in Q-spoiling from the other components (216, 218, 220, 223) of the receive circuit 202. Moreover, closing the switch circuit 214 during transmit mode operation substantially electrically isolates the matching impedance 216, the second transmission line 218, the second reactive impedance 220, and the amplifier input impedance 223 from the antenna reactive impedance elements 222 that is coupled to the first end portion 210-1 of the first transmission line 210.

In an example receive circuit 202, a combined impedance of the first transmission line 210 and the first reactive impedance circuit 212 primarily depends upon a phase length of the first transmission line 210. The first reactive impedance circuit 212 is configured so that a combined impedance of the first transmission line 210 and the first reactive impedance circuit 212 at a location at the first end 210-1 of the first transmission line 210, across the antenna impedance matching element 222′, will be mostly inductive when switching element 214 is closed, and in resonance with the antenna impedance matching element 222′. This parallel resonant circuit produces a resulting high impedance at the antenna impedance matching element 222′ required to effect Q-spoiling, which reduces current flow within the antenna 204.

### MRI Receive Mode Operation of the Receive Circuit

During MRI receive mode operation, the switch circuit 214 is open, it provides a high impedance that isolates and decouples an RF signal on line 226-1 from ground. When the switch is open, the first transmission line 210 and the second transmission line 218 are electrically coupled in series. When closed, the switch circuit 214 effectively acts as an open circuit between 226-1 and the left side of matching impedance 216. When open, the switch circuit 214 has no effect on the remainder of the circuit. When closed, the switch circuit 214 effectively acts as an open circuit between signal conductor 226-1 and ground. The receive circuit 202 uses the first transmission line portion 210, the first reactive impedance 212, the matching impedance 216, the second transmission line 218, the second reactive impedance 220, and amplifier impedance 223 to perform an amplifier decoupling function in which these components (210, 212, 216, 218, 220, 223) are in resonance with the antenna impedance matching element 222′. Stated differently, the first combined impedance (comprising transmission line 210, the first reactive impedance 212, the matching impedance 216) and the second combined impedance (comprising the second transmission line 218, the second reactive impedance 220, and amplifier impedance 223) operate together to function as an impedance transformation circuit that produces an impedance seen at a circuit location at the first end 210-1 of the first transmission line 210, across the antenna impedance matching element 222′, that is resonant with the antenna impedance matching element 222′ and that is greater than antenna impedance matching element 222′, thereby reducing current within the antenna 204, while permitting transmission of a voltage signal from the antenna 204 to the amplifier circuit 206. The reduced current within the antenna 204 reduces parasitic induction with neighbor antennas (not shown).

The length of the second transmission line 218, together with its characteristic impedance and the frequency of operation determines the electrical phase length of the second transmission line 218. During receive mode operation, the frequency typically will be the Larmor frequency. In an example receive circuit 202, a collective impedance of the second transmission line 218 and the second reactive impedance circuit 220 primarily depends upon a phase length of the second transmission line 220. The second reactive impedance circuit 220 is configured so that when the switching circuit 214 is turned “off,” (i.e., in its high-resistance state), the input impedance 223 of the amplifier circuit 206 is transformed through the phase shift imparted by the first transmission line 210, the first reactive impedance circuit 212, the matching impedance circuit 216, the second transmission line 218, and the second reactive impedance 220. The second reactive impedance circuit 220 is configured to contribute to this phase shift such that the input impedance 223 of the amplifier circuit 206 is transformed into an impedance that is in resonance with the antenna impedance matching element 222′, thereby creating a parallel resonant circuit having a high impedance across the antenna impedance matching element 222′, effectively blocking current in the antenna 204. This blocking renders the antenna 204 far less capable of coupling to its neighbor antennas (not shown) but allows it to remain sensitive to the MRI voltage signals that it is intended to receive.

### Switch Circuit

Referring to FIG. 7, an example implementation of the RF switch circuit 214 is shown that using a diode switch 702 coupled between signal conductor 226-1 and ground. A switch control circuit 704 is coupled to provide a control signal on line 706 to control on/off state of the diode 702 in response to MRI mode of operation. During an MRI transmit mode, the switch control circuit 704 provides a DC turn-on activation control voltage to the diode switch 702 causing the diode switch 702 to turn on, corresponding to closing of the RF switch 214, to provide an RF short circuit between signal conductor 226-1 and ground. During an MRI receive mode, the switch control circuit 704 does not provide a DC turn-on activation voltage to the diode switch 702 causing the switch 702 to be turned off, to provide an open circuit path between signal conductor 226-1 and ground, corresponding to opening of the RF switch 214.

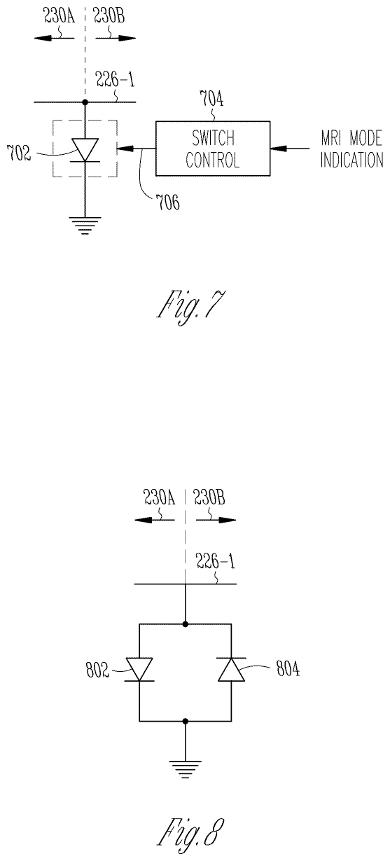

Referring to FIG. 8, an example implementation of the switch circuit 214 is shown using first and second cross-coupled diodes pairs 802, 804 connected between the signal line 226-1 and ground. During MRI transmit mode, an RF excitation signal induces an RF voltage level in the receive circuit 202 at signal conductor 226-1 that has a threshold voltage large enough in magnitude to automatically turn on the first and second cross-coupled diodes 802, 804, corresponding to closing of the RF switch 214, providing an RF short circuit path from signal conductor 226-1 to ground. During RF receive mode, when signals produced by changing magnetic moments of the nuclei of interest are transformed into electrical RF receive signals in the local receive antennas the RF voltage level in the receive circuit 202 at signal conductor 226-1 does not have a large enough voltage magnitude to turn on the cross-coupled diodes 802, 804, corresponding to closing of the RF switch 214, causing the cross-coupled diodes 802, 804 to provide an open circuit between signal conductor 226-1 and ground.

Although the example switch circuits are disclosed as including diodes, alternate switch circuit implementations can include a field effect transistor or a relay circuit, for example.

The above description is presented to enable any person skilled in the art to create and use an MRI RF receive circuit. Various modifications to the examples will be readily apparent to those skilled in the art, and the generic principles defined herein may be applied to other examples and applications without departing from the spirit and scope of the invention. In the preceding description, numerous details are set forth for the purpose of explanation. However, one of ordinary skill in the art will realize that the examples in the disclosure might be practiced without the use of these specific details. In other instances, well-known processes are shown in block diagram form in order not to obscure the description of the invention with unnecessary detail. Identical reference numerals are used in some places to represent different views of the same or similar items in different drawings. Thus, the foregoing description and drawings of embodiments and examples are merely illustrative of the principles of the invention. Therefore, it will be understood that various modifications can be made to the embodiments by those skilled in the art without departing from the spirit and scope of the invention, which is defined in the appended claims.

1. A radio frequency (RF) receive circuit for use in a magnetic resonance imaging (MRI) scanner, the RF circuit comprising:
an antenna including multiple reactive impedance elements electrically coupled in a loop configuration;
an amplifier input impedance;
a first transmission line electrically coupled in parallel with at least one reactive impedance element;
a second transmission line electrically coupled in parallel with the amplifier input impedance;
a first reactive impedance circuit electrically coupled to the first transmission line and to the second transmission line, between the first transmission line and the second transmission line;
an RF switch circuit electrically coupled between a first combined impedance, that includes the first transmission line and the first reactive impedance circuit, and a second combined impedance, that includes the second transmission line and the amplifier input impedance;
wherein the RF switch circuit is operable to electrically isolate the second combined impedance from the first combined impedance when the RF switch is closed and to electrically couple the second combined impedance to the first combined impedance when the RF switch is open;
wherein, when the RF switch is closed, the first combined impedance transforms impedance of the RF switch circuit to be in resonance with the at least one antenna impedance element; and
wherein, when the RF switch is open, the first combined impedance and the second combined impedance together transform the amplifier input impedance to be in resonance with the at least one antenna impedance element.

2. The circuit of claim 1 further including:
a matching impedance circuit electrically coupled to the first reactive impedance and the second transmission line, located between the RF switch circuit and the second transmission line;
wherein, when the RF switch is open, the matching impedance is operable to match the first combined impedance and the second combined impedance to prevent reflection of transmission line signals.

3. The circuit of claim 1,
wherein the second combined impedance includes a second reactive impedance circuit electrically coupled to the second transmission line, between the second transmission line and the amplifier input impedance; and
wherein, when the RF switch is open, the second reactive impedance circuit imparts a phase length such that collective phase lengths of the first combined impedance and the second combined impedance transform the amplifier input impedance to be in resonance with the at least one antenna impedance element.

4. The circuit of claim 1,
a matching impedance circuit electrically coupled to the first reactive impedance and the second transmission line, between the RF switch circuit and the second transmission line; and
a second reactive impedance circuit electrically coupled to the second transmission line, between the second transmission line and the amplifier input impedance; and
wherein the second combined impedance includes the second reactive impedance circuit;
wherein, when the RF switch is open, the matching impedance is operable to match the first combined impedance and the second combined impedance to prevent reflection of transmission line signals; and
wherein, when the RF switch is open, the second reactive impedance circuit impedance imparts a phase length such that collective phase lengths of the first combined impedance and the second combined impedance transform the amplifier input impedance to be in resonance with the at least one antenna impedance element.

5. The circuit of claim 1,
wherein the RF switch circuit includes at least one diode.

6. The circuit of claim 1,
wherein the RF switch circuit includes first and second cross-coupled diodes.

7. The circuit of claim 1,
wherein the RF switch is configured to close automatically in response to an RF signal received at the antenna having a threshold value; and
wherein the RF switch is configured to open automatically in response to an RF signal received at the antenna having below a threshold value.

8. The circuit of claim 1,
wherein the RF switch is configured to close in response to a control signal during excitation mode operation of an MRI system; and
wherein the RF switch is configured to open in response to a control signal during receive mode operation of the MRI system.

9. The circuit of claim 1,
wherein a first transmission line includes a first coaxial cable; and
wherein the second transmission line includes a second coaxial cable.

10. The circuit of claim 1,
wherein a first transmission line includes a first coaxial cable;
wherein the second transmission line includes a second coaxial cable; and
wherein the switch circuit includes at least one diode electrically coupled between a signal line of the first coaxial transmission line and ground.

11. A radio frequency (RF) receive circuit for use in a magnetic resonance imaging (MRI) scanner, the RF circuit comprising:
an antenna including multiple reactive impedance elements electrically coupled in a loop configuration;
an amplifier input impedance;
a first transmission line including a first end portion and a second end portion, wherein at least one reactive impedance element is electrically coupled in parallel with the first transmission line at the first end portion of the first transmission line;
a second transmission line including a first end portion and including a second end portion electrically, wherein the amplifier input impedance is electrically coupled in parallel with the second transmission line at the second end portion of the second transmission line;
a first reactive impedance circuit electrically coupled to the first transmission line and with the second transmission line, between the second end portion of the first transmission line and the first end portion of the second transmission line;
an RF switch circuit electrically coupled in parallel with the first transmission line and the second transmission line, between a first combined impedance, that includes the first transmission line and the first reactive impedance circuit, and a second combined impedance, that includes the second transmission line and the amplifier input impedance;
wherein the RF switch circuit is operable to electrically isolate the second combined impedance from the first combined impedance when the RF switch is closed and to electrically couple the second combined impedance to the first combined impedance when the RF switch is open;
wherein, when the RF switch is closed, the first combined impedance transforms impedance of the RF switch circuit seen at the first end portion of the first transmission line to be in resonance with the at least one antenna impedance element; and
wherein, when the RF switch is open, the first combined impedance and the second combined impedance together transform of the amplifier input impedance seen at the first end portion of the first transmission line to be in resonance with the at least one antenna impedance element.

12. The circuit of claim 11 further including:
a matching impedance circuit electrically coupled to the first reactive impedance and the second transmission line, located between the RF switch circuit and the first end portion of the second transmission line;
wherein, when the RF switch is open, the matching impedance is operable to match the first combined impedance and the second combined impedance to prevent reflection of transmission line signals.

13. The circuit of claim 11,
wherein the second combined impedance includes a second reactive impedance circuit electrically coupled to the second transmission line, between the second end portion of the second transmission line and the amplifier input impedance; and
wherein, when the RF switch is open, the second reactive impedance circuit impedance imparts a phase length such that collective phase lengths of the first combined impedance and the second combined impedance transform the amplifier input impedance seen at the first end portion of the first transmission line to be in resonance with the at least one antenna impedance element.

14. The circuit of claim 11,
a matching impedance circuit electrically coupled between the first reactive impedance and the second transmission line, between the RF switch circuit and the first end portion of the second transmission line; and
a second reactive impedance circuit electrically coupled to the second transmission line, between the second end portion of the second transmission line and the amplifier input impedance; and
wherein the second combined impedance includes the second reactive impedance circuit;
wherein, when the RF switch is open, the matching impedance is operable to match the first combined impedance and the second combined impedance to prevent reflection of transmission line signals; and
wherein, when the RF switch is open, the second reactive impedance circuit impedance imparts a phase length such that collective phase lengths of the first combined impedance and the second combined impedance transform the amplifier input impedance seen at the first end portion of the first transmission line to be in resonance with the at least one antenna impedance element.

15. The circuit of claim 11,
wherein the RF switch circuit includes at least one diode.

16. The circuit of claim 11,
wherein the RF switch circuit includes first and second cross-coupled diodes.

17. The circuit of claim 11,
wherein the RF switch is configured to close automatically in response to an RF signal received at the antenna having a threshold value; and
wherein the RF switch is configured to open automatically in response to an RF signal received at the antenna having below a threshold value.

18. The circuit of claim 11,
wherein the RF switch is configured to close in response to a control signal during excitation mode operation of an MRI system; and
wherein the RF switch is configured to open in response to a control signal during receive mode operation of the MRI system.

19. The circuit of claim 11,
wherein a first transmission line includes a first coaxial cable; and
wherein the second transmission line includes a second coaxial cable.

20. The circuit of claim 11,
wherein a first transmission line includes a first coaxial cable;
wherein the second transmission line includes a second coaxial cable; and
wherein the switch circuit includes at least one diode electrically coupled between a signal line of the first coaxial transmission line and ground.
